(19) United States
(12) Patent Application Publication
(10) Pub. No.: US 2025/0375813 A1
(43) Pub. Date: Dec. 11, 2025

(54) METHOD FOR CONNECTING ELECTRONIC COMPONENTS

(71) Applicant: Heraeus Electronics GmbH & Co. KG, Hanau (DE)

(72) Inventors: Tamira STEGMANN, Hanau (DE); Stefan GUNST, Hanau (DE); Andre SCHWÖBEL, Hanau (DE); Karsten DURST, Darmstadt (DE); Enrico BRUDER, Darmstadt (DE)

(21) Appl. No.: 19/225,525

(22) Filed: Jun. 2, 2025

(30) Foreign Application Priority Data
Jun. 6, 2024 (EP) 24180460.8

(51) Int. Cl. B22F 7/06; B22F 1/05; B22F 1/102; B22F 1/107

(52) U.S. Cl. CPC B22F 7/064; B22F 1/05; B22F 1/102; B22F 1/107; B22F 2301/255; B22F 2304/10; B22F 2998/10; B22F 2999/00

(57) ABSTRACT

A method for connecting electronic components, comprising (1) providing a sandwich arrangement comprising two electronic components A and B each comprising metal contact surfaces and a metal sintering composition located between a metal contact surface A′ of the electronic component A and a metal contact surface B′ of the electronic component B, (2) optionally, drying the metal sintering composition and (3) sintering the sandwich arrangement, wherein the metal sintering composition comprises, based on its non-volatile content, 80 to 100 wt. % of metal particles (i) having a particle size D90 in the range from 1 to 20 μm, wherein the metal contact surface A′ has an arithmetic mean roughness RaA and the metal contact surface B′ has an arithmetic mean roughness RaB, and wherein at least one of the quotients RaA/D90 and RaB/D90 is in the range from 0.05 to 0.3.

### CROSS-REFERENCE TO RELATED APPLICATION

This application claims priority pursuant to 35 U.S.C. 119 (a) to European Patent Application No. 24180460.8, filed Jun. 6, 2024, which application is incorporated herein by reference in its entirety.

### FIELD OF THE INVENTION

The invention relates to a method for connecting electronic components.

### BACKGROUND

The term “electronic component” as used herein refers to components that are used in electronics and each have at least one metallized contact surface or a contact surface made of metal, wherein the metal or the metallization can be, for example, alloyed or unalloyed copper, silver, gold, palladium, aluminum or nickel. Examples of such electronic components comprise diodes, LEDs (light emitting diodes), dies, IGBTs (insulated-gate bipolar transistors), MOSFETs (metal oxide semiconductor field effect transistors), ICs (integrated circuits), sensors, heat sinks, resistors, capacitors, coils, connectors (e.g., clips), base plates, antennas, lead frames, PCBs (printed circuit boards), flexible electronics, metal-ceramic substrates such as DCB substrates (direct copper bonded substrates), IMS (insulated metal substrate) and the like.

In the field of power and consumer electronics, sintering of electronic components is a common method. Metal sintering paste is often used as a bonding material, the main components of which are dispersed sinterable metal particles. Prominent examples of such metal sintering pastes comprise silver sintering pastes known to a person skilled in the art. Sintered connection technology is a very simple method for the stable connection of components, whereby the components to be connected are transferred into a sandwich arrangement with their contact surfaces facing one another with sintered connection material applied between them, for example metal sintering paste. The sandwich arrangement created using metal sintering paste is then subjected to a drying and sintering step, during which the mechanically strong, electrically and thermally conductive connection between the components is formed. The mechanically strong connection of two components means fixing one component to or on the second component via their respective contact surfaces.

The object of the invention was to find a method for connecting electronic components which allows said sandwich arrangements to be produced with particularly high connection strength.

The object was achieved with a fine-tuning between roughness, more precisely the arithmetic mean roughness Ra, of one or both of the metal contact surfaces of electronic components to be connected on the one hand and the use of a metal sintering composition with metal particles having a certain particle size D90 on the other hand; it has been found that compliance with a certain quotient Ra/D90 is essential to the invention. Accordingly, the invention relates to a method for connecting electronic components, comprising (1) providing a sandwich arrangement comprising two electronic components A and B each comprising metal contact surfaces and a metal sintering composition located between a metal contact surface A′ of the electronic component A and a metal contact surface B′ of the electronic component B, (2) optionally, drying the metal sintering composition and (3) sintering the sandwich arrangement, wherein the metal sintering composition comprises, based on its non-volatile content, 80 to 100 wt. % (% by weight) of metal particles (i) having a particle size D90 in the range from 1 to 20 μm, wherein the metal contact surface A′ has an arithmetic mean roughness RaA and the metal contact surface B′ has an arithmetic mean roughness RaB, and wherein at least one of the quotients RaA/D90 and RaB/D90 is in the range from 0.05 to 0.3.

The term “non-volatile content” as used herein means the content free of volatile substances, wherein “volatile substances” means substances having a boiling or decomposition point ≤280° C.; examples comprise, in particular, such organic solvents. The metal sintering composition may be free of volatile substances as defined.

The metal sintering composition may be a solid composition, for example a metal sintering preform. A metal sintering preform is a sheet-like piece of non-sintered metal sintering composition, e.g., dried and non-sintered metal sintering composition, for example 5 to 300 μm thin; it can be produced, for example, by applying a non-solid metal sintering composition to a flat support, drying without sintering and then peeling off. Such a solid metal sintering composition is characterized by a low content of volatile substances.

The metal sintering composition is preferably a non-solid composition with a more or less pronounced liquid, in particular pasty, consistency. Preferred examples comprise so-called metal sintering pastes. In a preferred embodiment, the invention therefore relates to a method for connecting electronic components, comprising (1) providing a sandwich arrangement comprising two electronic components A and B each comprising metal contact surfaces and a non-solid metal sintering composition located between a metal contact surface A′ of the electronic component A and a metal contact surface B′ of the electronic component B, (2) optionally, but preferably, drying the non-solid metal sintering composition and (3) sintering the sandwich arrangement, wherein the non-solid metal sintering composition consists of:
(i) 50 to 90 wt. %, preferably 60 to 85 wt. %, in particular 70 to 85 wt. % of metal particles having a particle size D90 in the range from 1 to 20 μm,
(ii) 10 to 50 wt. %, preferably 15 to 40 wt. %, in particular 15 to 30 wt. % of at least one organic solvent, and,
(iii) 0 to 20 wt. %, preferably 0 to 10 wt. %, in particular 0 to 5 wt. %, specifically 0.1 to 5 wt. % or even only 0.2 to 3 wt. % of at least one component other than components (i) and (ii), and, wherein the metal contact surface A′ has an arithmetic mean roughness RaA and the metal contact surface B′ has an arithmetic mean roughness RaB, and wherein at least one of the quotients RaA/D90 and RaB/D90 is in the range from 0.05 to 0.3.

Drying is understood to mean the removal of volatile substances, in particular organic solvents, from the applied and in particular non-solid metal sintering composition. Steps (1), (2) and (3) form a step sequence of type (1)-(2)-(3) with step (2) as an optional step. In one embodiment of the method according to the invention, step (1) can comprise drying and step (2) can thus be omitted; in another embodiment, step (1) does not comprise drying or only partially comprises drying and the optional step (2) can be omitted or can take place preferentially; if step (2) is omitted here, it can take place in the course of step (3) or overlap with it. It may also be the case that drying is not necessary and is therefore omitted.

The electronic components A and B each comprise-unless they are already made of metal—at least one metal contact surface A′ or B′ of one of the types already mentioned above. Said sandwich arrangement is carried out via the metal contact surfaces A′ and B′ within the scope of the method according to the invention.

The metal contact surface A′ preferably has an arithmetic mean roughness RaA in the range from 0.1 to 2.5 μm; the range from 0.5 to 2.0 μm is particularly preferred, in particular the range from 0.75 to 1.5 μm. The same applies to the arithmetic mean roughness RaB of the metal contact surface B′, which is also preferably in the range from 0.1 to 2.5 μm, particularly preferably in the range from 0.5 to 2.0 μm and in particular in the range from 0.75 to 1.5 μm.

As already mentioned, an essential condition of the invention is that at least one of the quotients RaA/D90 and RaB/D90 is in the range from 0.05 to 0.3.

Ra stands for the arithmetic mean roughness according to the version of DIN EN ISO 4287 valid on the date of filing. For example, the confocal microscope μsurf custom (NanoFocus AG, Germany) can be used to determine the mean roughness Ra. For this purpose, 3D images of the surface are taken at the metal contact surface A′ and/or B′. By means of the software μSoft Analysis Premium (7.4.8872; NanoFocus AG, Germany), the microscopic 3D images can be analyzed. For this purpose, any deflection of the metal contact surfaces A′ and/or B′ in the 3D images must first be corrected. Then, the mean roughness Ra can be obtained from the roughness profile of the surface using a Gaussian filter.

An arithmetic mean roughness RaA or RaB in the desired and preferred range from 0.1 to 2.5 μm can be set using suitable techniques. Examples of suitable techniques comprise abrasive grinding, blasting, polishing, chemical etching and laser structuring.

Abrasive grinding (wet or dry) can be carried out, for example, by means of rotating grinding wheels or grinding belts that can be moved in a longitudinal or transverse direction in manually operated or automated systems. Examples of abrasive materials comprise diamond and cubic boron nitride. The grain sizes of the abrasive materials can, for example, be in the range from 30 μm to 150 μm and can be selected according to the desired material removal.

During blasting, the metal contact surface in question can be treated by bombarding it with particles such as sand or glass beads. Suitable diameters of the blasting agent particles are, for example, 40 to 70 μm. The blasting agent is projected at high speed onto the surface to be treated, preferably using a compressed air blasting system with a pressure in the range from 2 to 10 bar, for example.

Polishing results in surface smoothing, i.e., a reduction of the arithmetic mean roughness. Polishing agents with small grain diameters, for example <20 μm, can be used for this purpose.

Chemical etching with, for example, iron (III) chloride can also remove material and thus produce a desired arithmetic mean roughness Ra without mechanically deforming the metal contact surface in question. For this purpose, the surface is immersed in the etching solution for several minutes to days, which then chemically attacks the surface and removes material.

In step (1) of the method according to the invention, the electronic components A and B are first brought into contact with one another. The contact is made via the metal sintering composition, which, as mentioned, may already be dried. For this purpose, a sandwich arrangement is provided in which the metal sintering composition is located between the electronic components A and B. A sandwich arrangement is an arrangement in which two electronic components A and B are located one above the other and are arranged substantially parallel to one another.

The sandwich arrangement can be produced according to a method known from the prior art. The relevant metal contact surface A′ or B′ of one of the electronic components A or B is provided with the metal sintering composition. Subsequently, the other component B or A is placed with its metal contact surface B′ or A′ on the metal sintering composition which has been applied to the metal contact surface A′ or B′ of the electronic component A or B.

The metal sintering composition can be applied to the relevant metal contact surface A′ or B′ of the electronic component A or B by means of conventional methods; in the case of a non-solid metal sintering composition, for example, by means of printing methods such as screen printing or stencil printing. Alternatively, application can also be carried out by means of dispensing technique, jetting, pin transfer or dipping. In the case of a solid metal sintering composition, the application can be carried out by placing or loading the solid metal sintering composition onto the relevant metal contact surface A′ or B′.

The wet layer thickness of non-solid metal sintering composition is preferably in the range from 20 to 400 μm. The preferred wet layer thickness depends, for example, on the selected application method. If the non-solid metal sintering composition is applied, for example, by screen printing, then a wet layer thickness of, for example, 20 to 60 μm may be preferred. If the application is carried out by stencil printing, for example, the preferred wet layer thickness may be in the range from 20 to 400 μm. For example, in the dispensing technique, the preferred wet layer thickness may be in the range from 20 to 400 μm depending on the application tool used. When using a hollow needle for example, the preferred wet layer thickness may be in the range from 20 to 100 μm, or when using a slot die that also functions as a doctor blade, the preferred wet layer thickness may be in the range from 50 to 400 μm.

Following the application of the metal sintering composition to the metal contact surface A′ or B′ of the electronic component A or B, the metal contact surface A′ or B′ of this electronic component A or B, which is provided with the optionally partially or completely dried metal sintering composition, is brought into contact with the corresponding metal contact surface B′ or A′ of the electronic component B or A to be connected thereto via the metal sintering composition. Thus, between the electronic components A and B to be connected, there is a layer of non-dried, partially or completely dried metal sintering composition forming the sandwich arrangement.

According to a preferred embodiment, the content of organic solvent in the metal sintering composition after drying is, for example, 0 to 5 wt. %, based on an original proportion of organic solvent in the metal sintering composition. In other words, during drying according to this preferred embodiment, for example, 95 to 100 wt. % of the organic solvent(s) originally contained in a metal sintering composition are removed.

The drying temperature in step (2) is preferably in the range from 100 to 150° C. Typical drying times are, for example, in the range from 5 to 45 minutes. To shorten the drying time, a vacuum can be used, for example a pressure in the range from 100 to 300 mbar.

After completion of step (1) or step (2), the sandwich arrangement is finally subjected to a sintering process.

Herein, sintering is understood to mean the connection of two electronic components A and B by heating while preventing the metal particles of the metal sintering composition from reaching the liquid phase. The solid mechanical connection formed is both electrically and thermally conductive; it, i.e., the metal sintered body formed between components A and B, consists substantially or completely of the metal of the metal particles (i).

This sintering step (3) of the method according to the invention is preferably carried out under pressure. In pressure sintering, the process pressure is preferably below 30 MPa and more preferably below 15 MPa. For example, the process pressure is in the range from 1 to 30 MPa and more preferably in the range from 5 to 15 MPa.

The actual sintering takes place at a temperature of, for example, 200 to 280° C.

The sintering time is, for example, in the range from 2 to 60 minutes, preferably 2 to 10 minutes.

The sintering process can take place in an atmosphere that is not subject to any particular restrictions. On the one hand, sintering can be carried out in an atmosphere that contains oxygen. On the other hand, it is also possible to carry out sintering in an oxygen-free atmosphere or in a vacuum. In the scope of the invention, an oxygen-free atmosphere is understood to mean an atmosphere in which the oxygen content is not more than 300 ppm by weight, preferably not more than 100 ppm by weight, and even more preferably not more than 50 ppm by weight.

Sintering is carried out in a conventional device suitable for sintering, in particular pressure sintering, in which the process parameters described above can be set.

A further essential condition of the invention is that the metal particles (i) included in the metal sintering composition used in the method according to the invention have a particle size D90 in the range from 1 to 20 μm, preferably in the range from >1 to 20 μm; in particular, the particle size D90 is in the range from 2 to 15 μm or very particularly in the range from 3 to 10 μm. The particle size D10 is preferably in the range from 0.2 to 2 μm, particularly preferably in the range from 0.5 to 2 μm, and in particular in the range from 0.7 to 1.5 μm.

The term “particle size D90” used herein in connection with the metal particles (i) means the primary particle diameter determinable by means of laser diffraction which is below a volume fraction of 90% of the particles, and the term “particle size D10” used herein in connection with the metal particles (i) means the primary particle diameter determinable by means of laser diffraction which is below a volume fraction of 10% of the particles. Laser diffraction measurements can be carried out using a corresponding particle size measuring instrument, for example a Mastersizer 3000 or Mastersizer 2000 from Malvern Instruments according to the wet determination process. In the wet determination process, for example, 1 g of metal particles of type (i) can be dispersed in 200 ml of ethanol using ultrasound during sample preparation.

The metal of the metal particles (i) can be, for example, copper or, in particular, silver. Sheathed metal particles are also possible, for example those in which in particular a sheath of silver or copper surrounds a core of another metal. The metal of the core can be a less noble metal, such as nickel or copper.

The metal particles (i) may be metal flakes (metal platelets), spherical metal particles or a mixture of metal flakes and spherical metal particles; metal flakes alone are preferred. The aspect ratio of the metal flakes can be, for example, >5:1, for example, from >5:1 to several hundred: 1. The aspect ratio of spherical metal particles is from 5:1 to 1:1, in particular from 3:1 to 1:1. The aspect ratio of particles describes the quotient of their largest and smallest length and thus their shape; in the case of metal flakes, the quotient of the largest and smallest length is the quotient of the largest length and the platelet thickness. It can be determined by scanning electron microscopy and evaluation of the electron microscopic images by determining the dimensions of a statistically significant number of individual particles.

The metal flakes can have a specific surface area, for example in the range from 1 to 5 m²/g. The spherical metal particles can have a specific surface area, for example in the range from 1 to 8 m²/g. The specific surface area in m²/g can be determined by means of BET measurement according to DIN ISO 9277:2014-01 (static volumetric measurement method, gas used: nitrogen).

The metal flakes can have a tapped density, for example in the range from 1 to 5 g/cm³. The spherical metal particles can have a tapped density, for example in the range from 3 to 6 g/cm³. Tapped density is the density of a solid that has been further compressed by tamping or vibrating, compared to its bulk density. Tapped density in g/cm³ can be determined according to DIN EN ISO 787-11:1995-10.

The metal particles (i) are usually coated. The weights given herein include the weight of the coating on the metal particles (i).

The aforementioned coating can be a firmly adhering layer on the surface of the metal particles (i). Typically, this is an organic coating. The content of the organic coating can, for example, be in the range from 0.5 to 2.0 wt. %, based on metal. In general, such an organic coating may comprise 90 to 100 wt. % of one or more fatty acids and/or fatty acid derivatives or amines. Examples of fatty acid derivatives comprise, in particular, fatty acid salts, fatty acid amides and fatty acid esters. Examples of fatty acids comprise caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), oleic acid (9-octadecenoic acid), arachidic acid (eicosanoic acid/icosanoic acid), behenic acid (docosanoic acid), lignoceric acid (tetracosanoic acid).

Metal particles of type (i) are commercially available. Said metal flakes are commercially available from companies such as Metalor or Ames Goldsmith. Said spherical metal particles are commercially available, for example, from Ames Goldsmith.

Component (i) of the metal sintering composition may be a single metal particle type of type (i) or a combination of two or more metal particle types of type (i); the decisive factor is that component (i) of the metal sintering composition is characterized by a particle size D90 in the range from 1 to 20 μm and preferably comprises only one type of metal, specifically silver.

Component (ii) optionally included in the metal sintering composition and in any case included in the non-solid metal sintering composition is at least one organic solvent. Examples of suitable organic solvents comprise terpineols, N-methyl-2-pyrrolidone, ethylene glycol, dimethylacetamide, 1-tridecanol, 2-tridecanol, 3-tridecanol, 4-tridecanol, 5-tridecanol, 6-tridecanol, isotridecanol, 2-ethyl-1,3-hexanediol, 2-(2-ethylhexyloxy) ethanol, benzyl alcohol, diethylene glycol monobutyl ether, dipropylene glycol monopropyl ether, dipropylene glycol monobutyl ether, dibasic esters (preferably dimethyl esters of glutaric, adipic or succinic acid or mixtures thereof), glycerol, diethylene glycol, triethylene glycol and aliphatic, in particular saturated aliphatic hydrocarbons having 5 to 32 C atoms, more preferably 10 to 25 C atoms and still more preferably 16 to 20 C atoms.

The optional component (iii), which is preferably included in the metal sintering composition, is at least one component other than metal particles (i) and organic solvent (ii). Examples comprise metal particles other than those of type (i), thermally decomposable metal precursors (metal precursor compounds), additives such as surfactants, defoamers and wetting agents and polymers, for example cellulose derivatives such as methyl cellulose, ethyl cellulose, ethyl methyl cellulose, carboxy cellulose, hydroxypropyl cellulose, hydroxyethyl cellulose and hydroxymethyl cellulose.

Based on the metal sintering composition, the sum of the wt. % of components (i) to (iii) is 100 wt. %. Accordingly, the non-solid metal sintering composition can be prepared by mixing the components (i) and (ii) or (i) to (iii). Conventional devices known to a person skilled in the art can be used, for example agitators, three-roll mills, jet mixers and/or dispersing mixers.

By means of the method according to the invention, a sintered sandwich arrangement can be obtained which is characterized by high connection strength and low porosity of the metal sintered body connecting the electronic components A and B of the sintered sandwich arrangement. The low porosity can be particularly low in the region of direct proximity between the metal sintered body and the metal contact surface(s) A′ and/or B′. This is believed to be a, if not the, key to the high connection strength, which can be measured as shear strength.

### EXAMPLES

### Examples 1 to 4 According to the Invention and Comparative Examples 5 and 6, General Procedure

1. Provision of Copper-Ceramic Substrates (27 mm×38 mm)

In examples 1, 2 and 4 according to the invention, copper-ceramic substrates with a copper contact surface modified with respect to the arithmetic mean roughness Ra were used. The corresponding modification was carried out by chemical etching using an aqueous iron (III) chloride solution (see Table 2).

In example 3 according to the invention, the copper contact surface was modified by grinding with respect to the arithmetic mean roughness Ra. For this purpose, the copper-ceramic substrate was fixed in an automated system by vacuum suction and its surface was machined in the longitudinal direction with a rotating diamond grinding wheel having a grain diameter of 126 μm while adding a cooling lubricant.

In comparative examples V5 and V6, instead of grinding, blasting was carried out with glass beads having a diameter in the range from 40 μm to 70 μm at 4 bar air pressure. 2. Production of silver sintering pastes

First, organic solvents and ethyl cellulose were homogenized at 80° C. to form a solvent system. Silver particles were then added to the solvent system in portions and completely dispersed. The raw materials used can be found in Table 1 (in % by weight).

TABLE 1
Composition of silver sintering pastes.

| | Silver | Ethyl | | |
|---|---|---|---|---|
| | particles | cellulose | Terpineol | Tridecanol |
| 1 | 82* | 0.36 | 8.82 | 8.82 |
| 2 | 82* | 0.36 | 8.82 | 8.82 |
| 3 | 82* | 0.36 | 8.82 | 8.82 |
| 4 | 85** | 0.3 | 7.35 | 7.35 |
| V1 | 82* | 0.36 | 8.82 | 8.82 |
| V2 | 85** | 0.3 | 7.35 | 7.35 |

*Fatty acid coated particles with D90 = 6.3 μm (see Table 2)
**Fatty acid coated particles with D90 = 3.0 μm (see Table 2)

### 3. Production of Sandwich Arrangements

The particular silver sintering paste (see Table 1) was applied to the copper surface of the copper-ceramic substrates by stencil printing in a wet layer thickness of 150 μm (see Table 2). This was followed by a drying step at 140° C. for 20 minutes in a nitrogen atmosphere in a convection oven. The dried silver sintering paste was then fitted with a silicon chip (4 mm×4 mm) metallized with silver on the underside using a semi-automated chip placement machine from Tresky. For this purpose, the chip was pressed into the dried paste for 2000 ms at a force of 2000 g at 80° C. The resulting sandwich arrangement was sintered in a hot press at 230° C. for 3 minutes in a nitrogen atmosphere (<100 ppm oxygen) under a pressure of 10 MPa.

### 4. Evaluation of the Connection Strength

To determine the connection strength, the shear strength of the sandwich arrangement was determined. The Nordson Dage 4000Plus test equipment was used for this purpose. A shearing chisel is placed at a height of 30 μm, measured from the height of the sintered sintering paste, on the chip, i.e., the upper component of the sandwich arrangement, and shears the chip at a speed of 300 μm/s at room temperature (21° C.). The force until the connection failed was recorded with a 20 kN load cell.

TABLE 2
Structure and evaluation of examples 1 to 4 according
to the invention and comparative examples V1 to V2.

| | Ra | D90 | | Shear | |
|---|---|---|---|---|---|
| | [μm] | [μm] | Ra/D90 | strength [MPa] | Evaluation |
| 1 | 0.370 | 6.3 | 0.059 | 40.7 | + |
| 2 | 0.720 | 6.3 | 0.114 | 44.3 | + |
| 3 | 1.470 | 6.3 | 0.233 | 39.5 | + |
| 4 | 0.370 | 3.0 | 0.123 | 41.2 | + |
| V5 | 2.430 | 6.3 | 0.386 | 30.7 | − |
| V6 | 2.430 | 3.0 | 0.810 | 21.5 | − |

1. A method for connecting electronic components, comprising (1) providing a sandwich arrangement comprising two electronic components A and B each comprising metal contact surfaces and a metal sintering composition located between a metal contact surface A′ of the electronic component A and a metal contact surface B′ of the electronic component B, (2) optionally, drying the metal sintering composition and (3) sintering the sandwich arrangement,
wherein the metal sintering composition comprises, based on its non-volatile content, 80 to 100 wt. % of metal particles (i) having a particle size D90 in the range from 1 to 20 μm,
wherein the metal contact surface A′ has an arithmetic mean roughness RaA and the metal contact surface B′ has an arithmetic mean roughness RaB, and
wherein at least one of the quotients RaA/D90 and RaB/D90 is in the range from 0.05 to 0.3.

2. The method according to claim 1, wherein the metal sintering composition is a solid composition or a non-solid composition.

3. A method for connecting electronic components, comprising (1) providing a sandwich arrangement comprising two electronic components A and B each comprising metal contact surfaces and a non-solid metal sintering composition located between a metal contact surface A′ of the electronic component A and a metal contact surface B′ of the electronic component B, (2) optionally, but preferably, drying the non-solid metal sintering composition and (3) sintering the sandwich arrangement,
wherein the non-solid metal sintering composition consists of:
(i) 50 to 90 wt. %, preferably 60 to 85 wt. %, in particular 70 to 85 wt. % of metal particles with a particle size D90 in the range from 1 to 20 μm,
(ii) 10 to 50 wt. %, preferably 15 to 40 wt. %, in particular 15 to 30 wt. % of at least one organic solvent, and
(iii) 0 to 20 wt. %, preferably 0 to 10 wt. %, in particular 0 to 5 wt. %, specifically 0.1 to 5 wt. % or even only 0.2 to 3 wt. % of at least one component other than components (i) and (ii), and
wherein the metal contact surface A′ has an arithmetic mean roughness RaA and the metal contact surface B′ has an arithmetic mean roughness RaB, and
wherein at least one of the quotients RaA/D90 and RaB/D90 is in the range from 0.05 to 0.3.

4. The method according to claim 1, wherein the arithmetic mean roughness RaA is in the range from 0.1 to 2.5 μm, preferably in the range from 0.5 to 2.0 μm, and in particular in the range from 0.75 to 1.5 μm.

5. The method according to claim 2, wherein the arithmetic mean roughness RaA is in the range from 0.1 to 2.5 μm, preferably in the range from 0.5 to 2.0 μm, and in particular in the range from 0.75 to 1.5 μm.

6. The method according to claim 1, wherein the arithmetic mean roughness RaB is in the range from 0.1 to 2.5 μm, preferably in the range from 0.5 to 2.0 μm, and in particular in the range from 0.75 to 1.5 μm.

7. The method according to claim 2, wherein the arithmetic mean roughness RaB is in the range from 0.1 to 2.5 μm, preferably in the range from 0.5 to 2.0 μm, and in particular in the range from 0.75 to 1.5 μm.

8. The method according to claim 1, wherein the metal of the metal particles (i) is copper or silver.

9. The method according to claim 2, wherein the metal of the metal particles (i) is copper or silver.

10. The method according to claim 1, wherein the metal particles (i) comprise sheathed metal particles.

11. The method according to claim 2, wherein the metal particles (i) comprise sheathed metal particles.

12. The method according to claim 1, wherein the metal particles (i) are metal flakes and/or spherical metal particles.

13. The method according to claim 2, wherein the metal particles (i) are metal flakes and/or spherical metal particles.

14. The method according to claim 1, wherein the metal particles (i) are coated.

15. The method according to claim 2, wherein the metal particles (i) are coated.

16. A sintered sandwich arrangement obtainable by a method according to claim 1.

17. A sintered sandwich arrangement obtainable by a method according to claim 2.
